(19) United States
(12) Patent Application Publication
(10) Pub. No.: US 2026/0308445 A1
(43) Pub. Date: Oct. 8, 2026

(54) QUANTUM DOT-CONTAINING COMPOSITION, WAVELENGTH CONVERSION MEMBER, AND METHOD FOR MANUFACTURING QUANTUM DOT-CONTAINING COMPOSITION

(71) Applicant: SHIN-ETSU CHEMICAL CO., LTD., Tokyo (JP)

(72) Inventors: Shinji AOKI, Annaka-shi (JP); Yoshihiro NOJIMA, Annaka-shi (JP); Kazuya TOBISHIMA, Annaka-shi (JP)

(73) Assignee: SHIN-ETSU CHEMICAL CO., LTD., Tokyo (JP)

(21) Appl. No.: 19/484,665

(22) PCT Filed: May 14, 2024
(86) PCT No.: PCT/JP2024/017800

§ 371 Date: Nov. 14, 2025

(30) Foreign Application Priority Data
May 25, 2023 (JP) 2023-086483

(51) Int. Cl. C09K 11/02; B82Y 20/00; B82Y 40/00; C08K 9/06; C09K 11/08; C09K 11/88

(52) U.S. Cl. CPC C09K 11/025; C08K 9/06; C09K 11/0883; C09K 11/883; B82Y 20/00; B82Y 40/00

(57) ABSTRACT

The present invention is a quantum dot-containing composition, including a quantum dot that emits fluorescence by excitation light, in which the quantum dot-containing composition is a mixture of the quantum dot and a polymerizable polymer composition, the quantum dot has a core-shell structure, an outermost shell is of ZnS, and a surface of the quantum dot contains a surface-coating layer having a siloxane bond, and the quantum dot has a peak intensity present between 1000 to 1200 cm⁻¹ that is larger than a peak intensity present between 2800 to 3000 cm⁻¹, measured by Fourier transform infrared spectrometry. This provides a quantum dot-containing composition that can improve the stability while keeping the property of the quantum dot.

### TECHNICAL FIELD

The present invention relates to a quantum dot-containing composition, a wavelength conversion member, and a method for manufacturing a quantum dot-containing composition.

### BACKGROUND ART

In a semiconductor nanoparticle single crystal, a size of the crystal being smaller than or equal to a Bohr radius of an exciton causes a strong quantum-confining effect to allow an energy level to be discrete. The energy level depends on the size of the crystal, and a light-absorbing wavelength and an emitting wavelength can be regulated by the crystal size.

In addition, emission of the semiconductor nanoparticle single crystal by recombination of excitons becomes highly efficient due to the quantum-confining effect, and the emission basically has a line spectrum, thereby attracting attention because achievement of particle size distribution with uniformized size enables emission with high luminance within a narrow band. Such a phenomenon due to the strong quantum-confining effect with the nanoparticles is called “quantum size effect”, and made is investigation for wide application and development of the semiconductor nanocrystal utilizing this property as a quantum dot (QD).

As the application of the quantum dot, utilization in a fluorescent material for a display has been investigated. Since achievement of the emission within a narrow band with high efficiency can express a color that cannot be produced by existing art, the quantum dot has attracted attention as a next-generation display material.

The displays advancing the utilization of the quantum dot at present include a quantum dot liquid crystal display, and its productization has been in progress. Attempted is conversion of color from white light or light emitted from a blue LED back light into green or red by passing the light through a quantum dot-containing wavelength conversion member.

The quantum dot has an active surface, and the quantum yield gradually decreases due to moisture or oxygen in the atmosphere, and thus, the quantum dot-containing wavelength conversion member has an essential examination item of improvement in stability.

Various investigation has been made on the stabilization of the wavelength conversion member containing the quantum dot. An example thereof includes gas-barrier sealing. The stability is improved by forming an inner layer in which the quantum dot is dispersed in an amphipathic polymer or a compatible polymer and by dispersing the quantum dot in another resin layer having low gas permeability.

Patent Document 1 publishes a method of forming a polymer bead by dispersing the QD in a hydrophobic resin layer, and subjecting this polymer bead to a surface modification so as to be dispersed in a hydrophilic polymer to be dispersed in the hydrophilic polymer.

Since the hydrophilic polymer tends to have a higher gas-barrier property than the hydrophobic polymer, the QD is dispersed with such a bilayer or multilayer structure. However, the gas-barrier property is insufficient for use in application that can be used in a high-temperature and high-humidity environment, such as use in a liquid crystal display unit, and thereby applying a method of sandwiching a QD film with a gas-barrier film to remove the effect by oxygen or water vapor.

Various investigation has been made also on a method for producing the polymer bead. Patent Document 2 discloses a method of producing a QD-containing polymer bead with a polysiloxane having an amino group and a polymerizable functional group, mixing a polymer having another polymerizable functional group, and forming an emulsion for further curing.

In this method, it is possible to increase the concentration of the QD contained in the polymer bead by increasing adhesion to the QD by using a polymer into which a ligand that coordinates to the QD surface is introduced, thereby improving stability. However, the stability provided by this method is still insufficient, and implementation is achieved by sandwiching with a barrier film.

### CITATION LIST

### Patent Literature

Patent Document 1: U.S. Pat. No. 9,708,532 B
Patent Document 2: JP 2016-111292 A
Patent Document 3: JP 2019-536653 A
Patent Document 4: US 2019/0322926 A

### SUMMARY OF INVENTION

### Technical Problem

However, use of the barrier film not only increases the cost but also necessarily increases the thickness. The liquid crystal display is required to be thin at present, and the thickness of the wavelength conversion member needs to be reduced. Thus, it is required to improve the stability without the barrier film. In addition, patterning is needed in considering use for a color filter, providing a protective layer such as the barrier film is unrealistic. The quantum dot itself is required to be stable.

Patent Document 3 is published as investigation of improving heat resistance and humidity resistance without the barrier film. In this method, the above multilayer resin composition using the polymer bead structure in Patent Document 1 is further treated with a silazane coating, and this method improves the stability. This method, however, has a problem of decrease in the quantum yield in the silazane coating photo-curing by irradiation with short ultraviolet ray (170 nm).

In addition, Patent Document 4 is published as another attempt. In this method, a ligand is coordinated with the quantum dot, a reactive substituent such as a vinyl group and a methacryl group is introduced in the ligand, then a silicone resin containing Si—H and a curing agent are mixed, and the mixture is applied as it is by spin coating and then heated for curing to produce a film with improved heat resistance and humidity resistance.

However, the Si—H-containing silicone resin and the quantum dot used have low compatibility, and dispersing the quantum dot at a high concentration causes aggregate. Thus, the compatibility needs to be improved by the ligand treatment, but a problem is that change in balance between a hydrophobic group and a hydrophilic group in coordinating the ligand easily causes the aggregate, which decreases the quantum yield.

In addition, it is important in application for the color filter to make the surface state of the quantum dot suitable for its patterning method. A photolithography method is employed in practice at present for color filters, including applying a photosensitive resin composition containing a pigment onto a glass substrate, drying the solvent, then subjecting the coating to mask-exposure with UV irradiation, removing the uncured portion by alkali development to form a color pattern, and repeating this process to form blue, red, and green patterns.

The photolithography method has many problems such as a large loss of the raw material because the uncured portion is wasted, the complex steps, and use of an expensive apparatus. Thus, an inkjet method has been investigated in recent years.

The inkjet method has competitiveness in terms of cost, such as no loss of the raw material, and producibility of a large-sized or large-area product without installation of an expensive apparatus. The inkjet method, however, has problems that the art of producing a fine nozzle is complex, a smaller nozzle causes clogging and unstable discharge, etc. For reduction in size, both the proven photolithography and the inkjet having cost competitiveness have been investigated.

Meanwhile, a problem for any of the photolithography and the inkjet is production of the resin composition containing the quantum dot at a high concentration with high dispersiveness. Dispersing the quantum dot at a high concentration has a problem of modification of the property of the resin after curing, such as, for example, insufficient curing according to the content of the quantum dot.

The present invention has been made to solve the above problems, and an object of the present invention is to provide a quantum dot-containing composition and a wavelength conversion member that can improve the stability while keeping the property of the quantum dot.

In addition, an object of the present invention is to provide a method for manufacturing a quantum dot-containing composition that can improve the stability while keeping the property of the quantum dot.

### Solution to Problem

The present invention has been made to achieve the above object, and provides a quantum dot-containing composition, comprising a quantum dot that emits fluorescence by excitation light, wherein the quantum dot-containing composition is a mixture of the quantum dot and a polymerizable polymer composition, the quantum dot has a core-shell structure, an outermost shell is of ZnS, and a surface of the quantum dot contains a surface-coating layer having a siloxane bond, and the quantum dot has a peak intensity present between 1000 to 1200 cm⁻¹ that is larger than a peak intensity present between 2800 to 3000 cm⁻¹, measured by Fourier transform infrared spectrometry.

The quantum dot-containing composition as above can improve the stability while keeping the property of the quantum dot.

In this case, the surface-coating layer may have any one or more reactive substituents of a vinyl group, an acryl group, a methacryl group, a hydroxy group, a phenolic hydroxy group, and an epoxy group.

This can introduce the substituent polymerizable with the polymerizable polymer in the surface-coating layer, and can improve the stability while keeping the property of the quantum dot.

In this case, a polymer contained in the polymerizable polymer composition may have any one or more of a vinyl group, an acryl group, a methacryl group, a hydroxy group, a phenolic hydroxy group, and an epoxy group as a substituent polymerizable with the reactive substituent.

This allows polymerization between the reactive substituent and the polymer, which yields not only inhibition of curing failure in polymerizing the polymer but also improvement of the dispersibility.

In addition, the present invention provides a wavelength conversion member being a cured product of the aforementioned quantum dot-containing composition.

The wavelength conversion member as above is a cured product of the quantum dot-containing composition that can improve the stability while keeping the property of the quantum dot, and therefore, the wavelength conversion member also can improve the stability while keeping the property of the quantum dot.

Further, the present invention provides a method for manufacturing a quantum dot-containing composition, comprising a quantum dot that emits fluorescence by excitation light, the method comprising: a surface treatment step of heating and mixing a solution containing a dispersed quantum dot in which ZnS is formed in an outermost shell, a ligand having a substituent capable of forming a siloxane bond and having a thiol group, and a solution containing a zinc precursor and a sulfur precursor, to coordinate the ligand while forming an additional ZnS on an outermost surface of the quantum dot; a surface-coating layer formation step of performing a reaction between the substituent capable of forming a siloxane bond and a compound capable of forming a siloxane bond and having a reactive substituent, to form a surface-coating layer having a siloxane bond, after the surface treatment step; and a mixing step of adding and mixing a polymerizable polymer composition containing a substituent polymerizable with the reactive substituent, after the surface-coating layer formation step.

The manufacturing method as above can form the surface-coating layer to deactivate the quantum dot while inhibiting decrease in emission efficiency of the quantum dot due to the surface treatment to improve the stability by performing the reaction of the ligand having the substituent capable of forming a siloxane bond while forming the ZnS shell. Further, disposing of the substituent polymerizable with the polymerizable polymer composition can yield not only inhibition of curing failure in polymerizing the polymer but also improvement in the dispersibility.

### Advantageous Effects of Invention

As above, the quantum dot-containing composition and the wavelength conversion member of the present invention can improve the stability while keeping the property of the quantum dot.

In addition, the method for manufacturing a quantum dot-containing composition of the present invention can improve the stability while keeping the property of the quantum dot.

### BRIEF DESCRIPTION OF DRAWINGS

FIG. 1 is a spectrum of Fourier transform infrared spectrometry (FT-IR) of a quantum dot of Example 1;

FIG. 2 is a spectrum of FT-IR of a quantum dot of Comparative Example 1; and

FIG. 3 is a flowchart of the method for manufacturing a quantum dot-containing composition of the present invention.

### DESCRIPTION OF EMBODIMENTS

Hereinafter, the present invention will be described in detail, but the present invention is not limited thereto.

As noted above, there has been a demand of the quantum dot-containing composition that can improve the stability while keeping the property of the quantum dot.

The present inventors have earnestly studied the above problem, and consequently found that the stability can be improved while keeping the property of the quantum dot by a quantum dot-containing composition including a quantum dot that emits fluorescence by excitation light, wherein the quantum dot-containing composition is a mixture of the quantum dot and a polymerizable polymer composition, the quantum dot has a core-shell structure, an outermost shell is of ZnS, and a surface of the quantum dot contains a surface-coating layer having a siloxane bond, and the quantum dot has a peak intensity present between 1000 to 1200 cm⁻¹ that is larger than a peak intensity present between 2800 to 3000 cm⁻¹, measured by Fourier transform infrared spectrometry. This finding has led to completion of the present invention.

In addition, as noted above, there has been a demand of the wavelength conversion member that can improve the stability while keeping the property of the quantum dot.

The present inventors have earnestly studied the above problem, and consequently found that the stability can be improved while keeping the property of the quantum dot by a wavelength conversion member being a cured product of the aforementioned quantum dot-containing composition. This finding has led to completion of the present invention.

Further, as noted above, there has been a demand of the method for manufacturing a quantum dot-containing composition that can improve the stability while keeping the property of the quantum dot.

The present inventors have earnestly studied the above problem, and consequently found that the stability can be improved while keeping the property of the quantum dot by a method for manufacturing a quantum dot-containing composition including a quantum dot that emits fluorescence by excitation light, the method including: a surface treatment step of heating and mixing a solution containing a dispersed quantum dot in which ZnS is formed in an outermost shell, a ligand having a substituent capable of forming a siloxane bond and having a thiol group, and a solution containing a zinc precursor and a sulfur precursor, to coordinate the ligand while forming an additional ZnS on an outermost surface of the quantum dot; a surface-coating layer formation step of performing a reaction between the substituent capable of forming a siloxane bond and a compound capable of forming a siloxane bond and having a reactive substituent, to form a surface-coating layer having a siloxane bond, after the surface treatment step; and a mixing step of adding and mixing a polymerizable polymer composition containing a substituent polymerizable with the reactive substituent, after the surface-coating layer formation step. This finding has led to completion of the present invention.

Hereinafter, the present invention will be described in detail, but the present invention is not limited thereto.

The quantum dot-containing composition of the present invention is a composition containing a material in which a surface-coating layer having a siloxane bond is formed in a surface of a quantum dot that emits fluorescence by excitation light. More specifically, the quantum dot-containing composition is a mixture of a quantum dot and a polymerizable polymer composition. In addition, the quantum dot-containing composition may be of composite particles in which a substituent condensation-polymerizable with the polymerizable polymer composition is introduced onto this surface-coating layer, or a mixture thereof.

### (Quantum Dot)

The shape of the quantum dot in the present invention is not particularly limited, and the quantum dot with any form can be used. The quantum dot is of mainly nanoparticles having a particle diameter of 10 nm or less, may be nanowire, nanorod, nanotube, nanocube, etc., and any shape may be applied.

For the quantum dot used in the present invention, any suitable material that emits fluorescence by excitation light such as, for example, a material selected from the group consisting of: II-VI group, III-V group, IV group, IV-VI-group, I-III-VI group, and II-IV-V group elements, a mixed crystal or an alloy thereof as a semiconductor material; or a compound having a perovskite structure can be used.

Specific examples include, but not limited to, a compound containing ZnS, ZnSe, ZnTe, CdS, CdSe, CdTe, AlN, AlP, AlAs, AlSb, GaN, GaP, GaAs, GaSb, InN, InP, InAs, InSb, Si, Ge, Sn, Pb, PbS, PbSe, PbTe, SnS, SnSe, SnTe, AgGaS₂, AgInS₂, AgGaSe₂, AgInSe₂, CuGaS₂, CuGaSe₂, CuInS₂, ZnSiP₂, ZnGeP₂, CdSiP₂, CdGeP₂, CsPbCl₃, CsPbBr₃, CsPbI₃, CsSnCl₃, CsSnBr₃, or CsSnI₃.

In addition, the quantum dot used in the present invention has a core-shell structure. A shell material capable of forming the core-shell structure is not particularly limited as long as the material has the outermost shell of ZnS, but the material preferably has a wide bandgap relative to the core material, preferably has low lattice mismatch, and preferably has a lower bandgap than ZnS being the outermost shell. The shell material may be freely combined according to the core material and the outermost shell material.

Examples of the specific shell material include ZnO, ZnS, ZnSe, ZnTe, CdS, CdSe, CdTe, AlN, AlP, AlAs, AlSb, GaN, GaP, GaAs, GaSb, InN, InP, InAs, InSb, BeS, BeSe, BeTe, MgS, MgSe, MgTe, PbS, PbSe, PbTe, SnS, SnSe, SnTe, CuF, CuCl, CuBr, and CuI. The above material may be selected as a single crystal or a plurality of mixed crystal, but is not limited thereto.

A method for manufacturing the quantum dot includes various methods such as a liquid-phase method and a gas-phase method, and is not particularly limited in the present invention. From the viewpoint of exhibiting high fluorescence efficiency, preferably used is the semiconductor nanoparticles obtained by using a hot soap method or a hot injection method in which a precursor species reacts in a high boiling-point nonpolar solvent having at high temperature. To impart dispersibility in the nonpolar solvent and to reduce surface defects, a ligand being an organic ligand is desirably coordinated on the surface.

The ligand preferably contains an aliphatic hydrocarbon from the viewpoint of the dispersibility. Examples of such a ligand include oleic acid, stearic acid, palmitic acid, myristic acid, lauric acid, decanoic acid, octanoic acid, oleylamine, stearyl(octadecyl)amine, dodecyl(lauryl)amine, decylamine, octylamine, octadecanethiol, hexadecanethiol, tetradecanethiol, dodecanethiol, decanethiol, octanethiol, trioctylphosphine, trioctylphosphine oxide, triphenylphosphine, triphenylphosphine oxide, tributylphosphine, and tributylphosphine oxide. These may be used singly, or a plurality of types thereof may be combined.

### (Ligand Having Thiol Group)

In addition, a ligand having a substituent capable of forming a siloxane bond is desirably coordinated on the quantum dot of the present invention in addition to the above ligand. The ligand having a substituent capable of forming a siloxane bond desirably has a substituent that interacts with or is adsorbed on the quantum dot surface.

Examples of the substituent that interacts or reacts with the quantum dot surface include an amino group, a carboxy group, a mercapto group, a phosphine group, a phosphine oxide group, a sulfonyl group, and a quaternary ammonium salt. Among these, the thiol group is preferable from the viewpoint of the outermost shell being of ZnS and strength of coordination ability and reactivity.

In addition, the quantum dot-containing composition of the present invention contains a surface-coating layer having a siloxane bond. For example, the quantum dot surface is coated by polysiloxane with a polymer. Thus, the ligand having a substituent coordinatable with the quantum dot surface desirably has the substituent capable of forming a siloxane bond.

The ligand having the substituent capable of forming a siloxane bond includes: compounds having an alkoxysilane such as a trimethoxysilyl group, a triethoxysilyl group, a dimethoxymethylsilyl group, a diethoxymethylsilyl group, a dimethylmethoxysilyl group, and an ethoxydimethylsilyl group; compounds having a silazane bond; compounds having a Si—OH bond; compounds having a Si—X (X: halogen) bond; and carboxylic acids. Since the reaction can proceed under a gentle condition of not generating an acid as a byproduct of the reaction, a ligand containing an alkoxysilane, a silazane, or Si—OH is preferably used.

### (Surface-Coating Layer)

The surface-coating layer of the quantum dot-containing composition of the present invention has a siloxane bond. More specifically, the quantum dot surface is desirably coated by polysiloxane with a polymer. Thus, desired is a reaction between: the above substituent capable of forming a siloxane bond, and contained in the ligand having a thiol group coordinatable with the quantum dot; and the compound capable of forming a siloxane bond and having a reactive substituent, to form the quantum dot-surface polymer-coating layer containing a polysiloxane.

In addition, the surface-coating layer of the present invention desirably has at least one or more reactive substituents polymerizable with a polymer contained in a polymerizable polymer composition, described later. The substituent polymerizable with the polymer is desirably contained in the surface-coating layer by forming a covalent bond therewith.

By forming the covalent bond, the polymer and the polymerizable substituent are hardly cleaved in a following purification procedure compared with a case of forming an association with the surface-coated quantum dot or a case of being contained so as to coordinate with the quantum dot surface or the surface-coating layer.

In addition, examples of the reactive substituent polymerizable with the polymer include a vinyl group, an acryl group, a methacryl group, a hydroxy group, a phenolic hydroxy group, an epoxy group, a sulfonyl group, a carboxyl group, and a thiol group. The substituent having not excessively strong acidity and having not excessively high coordination ability with the quantum dot is preferable because aggregation can be certainly inhibited. Specifically, a vinyl group, an acryl group, a methacryl group, a hydroxy group, a phenolic hydroxy group, and an epoxy group are preferable.

### (Spectrum by FT-IR)

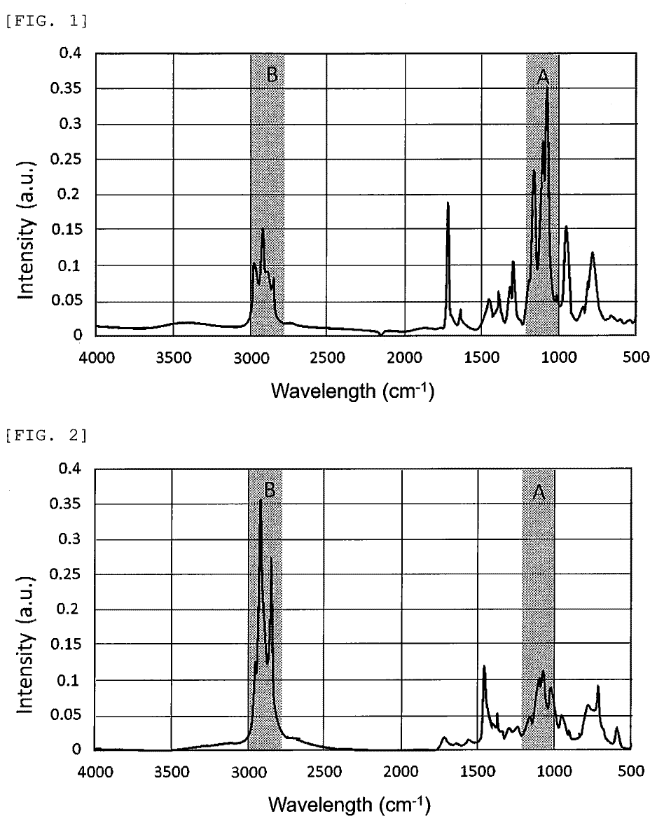

As shown in FIG. 1, the surface-coated quantum dot exhibits a peak intensity present between 1000 to 1200 cm⁻¹ being larger than a peak intensity present between 2800 to 3000 cm⁻¹ by FT-IR.

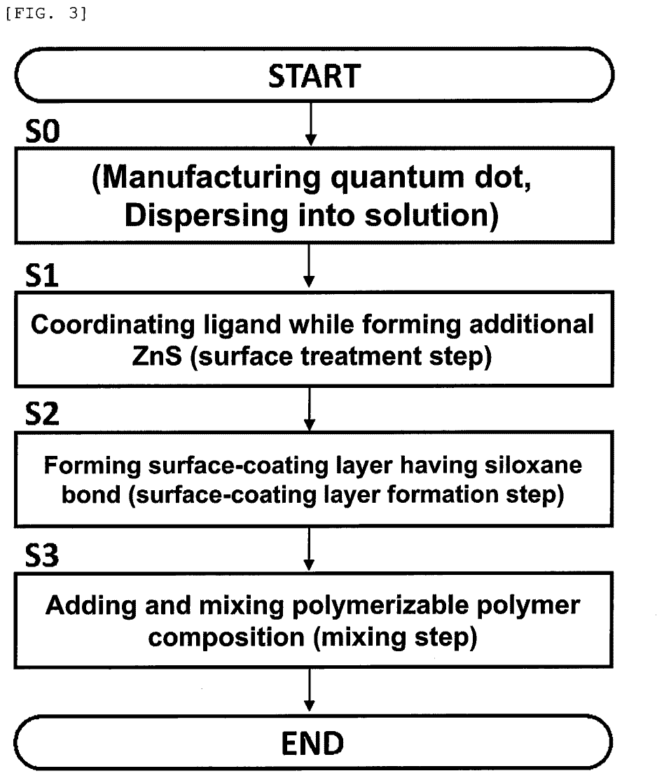

As shown in FIG. 2, a case where the peak intensity present between 1000 to 1200 cm⁻¹ being equal to or less than the peak intensity present between 2800 to 3000 cm⁻¹ deteriorates properties of the quantum dot, such as internal quantum efficiency, or deteriorates the stability.

### (Polymerizable Polymer Composition)

The quantum dot-containing composition of the present invention is a mixture of the quantum dot and the polymerizable polymer composition. The polymerizable polymer composition is composed of, for example, the polymer being a base polymer and a polymerization initiator, and may contain an organic solvent, a polymerizable crosslinker, a photo-acid generator, an oxidation inhibitor, a light scattering agent, etc. in addition thereto.

As the polymer, a polymer derived from each of acrylic acid, methacrylic acid, an acrylate ester, or a methacrylate ester, a copolymer in which a plurality of them are combined, a polymer having glycidyl (meth)acrylate as a repeating unit, and a polymer having a siloxane skeleton, a urethane skeleton, a silphenylene skeleton, a norbornene skeleton, a fluorene skeleton, or an isocyanurate skeleton can be suitably used, and the polymer to be used may be appropriately selected according to the application.

Examples thereof include an acrylic resin, an alkyd resin, a melamine resin, an epoxy resin, a silicone resin, polyvinyl alcohol, polyvinylpyrrolidone, polyimide precursors such as a polyamide, a polyamide-imide, and a polyimide, and an esterified product thereof, and a reaction product between a tetracarboxylic dianhydride and a diamine.

In addition, a polymerizable substituent polymerizable with the reactive substituent is preferably introduced in these polymers, and use in combination with a polymerization initiator enables curing. Examples of a radically polymerizable substituent include a vinyl group, an acryl group, a methacryl group, and a thiol group, and examples of a cationically polymerizable substituent include a hydroxy group, a phenolic hydroxy group, and an epoxy group. The polymer preferably has any one or more of them. In addition, examples thereof also include a glycidyl group, an oxetanyl group, and an isocyanate group, and any of them can be suitably used. In addition, a carboxy group may be additionally introduced in order to impart alkali developability.

In addition, the quantum dot-containing composition of the present invention preferably contains a polymerization initiator. The polymerization initiator includes a thermal or photo-polymerization initiator, and any of them can be suitably used according to the base polymer. Examples of the photo-radical polymerization initiator include Irgacure 290, Irgacure 651, Irgacure 754, Irgacure 184, Irgacure 2959, Irgacure 907, Irgacure 369, Irgacure 379, Irgacure 819, and Irgacure 1173 as the Irgacure® series commercially available from BASF SE. In addition, examples thereof include TPO and Darocure 1173 as the Darocure® series. In addition, a known thermal radical polymerization initiator and photo-cation polymerization initiator may be contained.

A content of the polymerization initiator is preferably 0.1 to 10 parts by mass, and further preferably 0.2 to 5 parts by mass based on 100 parts by mass of the polymer to be added.

The quantum dot-containing composition of the present invention may contain a solvent in order to improve its coatability. The solvent is favorably an organic solvent from the viewpoint of compatibility with the quantum dot, and is a ketone, an alkylene glycol ether, an alcohol, and an aromatic compound, for example. Suitably used are: acetone, methyl ethyl ketone, cyclohexanone, etc. from the group of ketone; methyl cellosolve (ethylene glycol monomethyl ether), butyl cellosolve (ethylene glycol monobutyl ether), methyl cellosolve acetate, ethyl cellosolve acetate, butyl cellosolve acetate, ethylene glycol monopropyl ether, ethylene glycol monohexyl ether, ethylene glycol dimethyl ether, diethylene glycol ethyl ether, diethylene glycol diethyl ether, propylene glycol monomethyl ether, propylene glycol monoethyl ether, propylene glycol monopropyl ether, propylene glycol monobutyl ether, propylene glycol monomethyl ether acetate, diethylene glycol methyl ether acetate, diethylene glycol ethyl ether acetate, diethylene glycol propyl ether acetate, diethylene glycol isopropyl ether acetate, diethylene glycol butyl ether acetate, diethylene glycol tertiary butyl ether acetate, triethylene glycol methyl ether acetate, triethylene glycol ethyl ether acetate, triethylene glycol propyl ether acetate, triethylene glycol isopropyl ether acetate, triethylene glycol butyl ether acetate, triethylene glycol tertiary butyl ether acetate, etc. from the group of alkylene glycol ether; methyl alcohol, ethyl alcohol, isopropyl alcohol, n-butyl alcohol, 3-methyl-3-methoxybutanol, etc. from the group of alcohol; and benzene, toluene, and xylene from the group of aromatic solvent.

In addition, the quantum dot-containing composition in the present invention may contain a polymerizable crosslinker, a photo-acid generator, an oxidation inhibitor, a light scattering agent, etc. in addition thereto, and the additive is not particularly limited as long as the additive does not affect coatability of the quantum dot-containing composition.

### (Method for Manufacturing Quantum Dot-Containing Composition)

The quantum dot-containing composition of the present invention can be manufactured by the following method exemplified in FIG. 3.

First, a quantum dot that emits fluorescence by excitation light in which ZnS is formed in the outermost shell is manufactured, or if already manufactured, the manufactured quantum dot is prepared, and dispersed in a solution (S0 in FIG. 3). As the method for manufacturing the quantum dot, the above-described liquid-phase method and gas-phase method can be exemplified.

Then, the solution in which the quantum dot is dispersed, the ligand having the substituent capable of forming a siloxane bond and a thiol group, and a solution containing a zinc precursor and a sulfur precursor are heated and mixed to coordinate the ligand while forming additional ZnS on the outermost surface of the quantum dot (S1 in FIG. 3; the surface treatment step).

The reason why the ligand is coordinated while forming ZnS as above is as follows.

When the ligand having the substituent capable of forming a siloxane bond and a thiol group is coordinated, it is common that a quantum dot coordinated with a ligand having a long-chain hydrocarbon is dispersed in a hydrophobic solvent, and a ligand having the substituent capable of forming a siloxane bond and the thiol group coordinatable onto the quantum dot surface are mixed to perform ligand exchange. In the ligand exchange reaction, conditions such as an addition amount, a heating temperature, a time, and light irradiation are appropriately modified according to the type of the ligand. The above method, however, is known to decrease the quantum yield at a certain amount.

Accordingly, for forming the ZnS shell, mixing the ligand into the solution of a zinc precursor and a sulfur precursor to form the ZnS shell can introduce the ligand without the decrease in the quantum yield, and can introduce a large amount of the ligand compared with the ligand exchange.

Then, a reaction between the substituent capable of forming a siloxane bond and a compound capable of forming a siloxane bond and having a reactive substituent is performed to form a surface-coating layer having a siloxane bond, after the surface treatment step (S2 in FIG. 3; the surface-coating layer formation step).

Specifically, a reaction with the quantum dot coordinated with the thiol, and having the substituent capable of forming a siloxane bond that is introduced in the surface-coating layer formation step to form a polysiloxane is performed to form the surface-coating layer having a siloxane bond.

As a typical method for forming a polysiloxane bond, a sol-gel method is suitably used. Since the quantum dot is unstable under an acidic condition or moisture, a sol-gel method under a basic condition or a sol-gel method using a Lewis acid catalyst are preferable, and a non-hydrolytic sol-gel method using diphenylsilanediol, tetramethyldisiloxanediol, etc., or a Lewis acid promoted sol-gel reaction (LANHSG) under a Lewis acid catalyst using an alkoxysilane having a reactive substituent is further preferable.

In addition, the surface-coating layer of the present invention desirably has at least one or more substituents polymerizable with the polymer contained in the aforementioned polymerizable polymer composition or skeleton structures having a similar structure. The substituent polymerizable with the polymer or the compound having the similar skeleton structure is desirably contained by forming a covalent bond with the surface-coating layer. A method for forming the covalent bond is not particularly limited. For example, suitably used are: a method in which the substituent capable of forming a siloxane bond is introduced in the compound having the substituent polymerizable with the polymer or the similar skeleton structure, and added during the above non-hydrolytic sol-gel reaction to contain the compound in the state of forming the covalent bond on the surface-coating layer; and a method in which the substituent polymerizable with the polymer contained in the polymerizable polymer composition is introduced during the above non-hydrolytic sol-gel reaction, and then a reaction with the polymer or the monomer is performed to be introduced on the surface-coating layer.

After the surface-coating layer formation step, the polymerizable polymer composition containing the substituent polymerizable with the reactive substituent is added and mixed to obtain the quantum dot-containing composition (S3 in FIG. 3; the mixing step).

Specifically, after the surface-coating layer is formed, an unreacted material is removed by purification, and the product is mixed with the polymerizable polymer composition to manufacture the quantum dot-containing composition. Formation of the surface-coating layer improves compatibility with the polymerizable polymer composition, which can manufacture the quantum dot-containing composition in which the quantum dot is uniformly dispersed without aggregate.

### (Wavelength Conversion Member Having Quantum Dot-Containing Composition)

The wavelength conversion member of the present invention is a resin composition, being a cured product of the quantum dot-containing composition manufactured by the above method. The form of the wavelength conversion member in the present invention is not particularly limited, and examples thereof include: a wavelength conversion film in which the quantum dot is dispersed in the polymerizable polymer composition by processing into a sheet and then curing; and a wavelength conversion color filter in which the composition is subjected to patterning as inkjet or a resist material.

A method for manufacturing (producing) the wavelength conversion member is not particularly limited. For example, the quantum dot-containing composition is applied and cured on a transparent film such as PET or a polyimide or a substrate material, and laminated to obtain the wavelength conversion member.

For applying the composition on the transparent film, a spraying method such as a spray and inkjet, spin-coating, and a bar coater can be used.

A method for curing the quantum dot-containing composition can be performed by, for example, heating the film on which the quantum dot-containing composition is applied at 60° C. for 2 hours and then 150° C. for 4 hours. In addition, the quantum dot-containing composition may be cured by using a photo-polymerization reaction. For example, the composition can be cured with a UV-LED irradiation apparatus by irradiation with light at a wavelength of 365 nm and a power of 4000 mW/cm² for 20 seconds. The method is not particularly limited, and may be appropriately modified according to the application.

Here, the substituent polymerizable with the polymer in the quantum dot-containing composition introduced on the surface-coating layer enables to manufacture the wavelength conversion member having high reliability after curing without aggregation or curing inhibition, which is preferable.

### EXAMPLE

Hereinafter, the present invention will be further specifically described by using Examples and Comparative Examples, but the present invention is not limited thereto. In the present Examples, a core-shell quantum dot of InP/ZnSe/ZnS was used as a quantum dot material.

### Example 1

### (Quantum Dot Core Synthesizing Step)

In a flask, 0.23 g (0.9 mmol) of palmitic acid, 0.088 g (0.3 mmol) of indium acetate, and 10 mL of 1-octadecene were added, and the mixture was heated and stirred under a reduced pressure at 100° C. to perform degassing for 1 hour while dissolving the raw materials.

Thereafter, the flask was purged with nitrogen, 0.75 mL (0.15 mmol) of a solution prepared by mixing tristrimethylsilylphosphine with trioctylphosphine at 0.2 M was added, and the temperature was raised to 300° C. The solution was colored from yellow to red, and generation of core particles was confirmed.

### (Quantum Dot Shell-Layer Synthesizing Step)

Subsequently, 2.85 g (4.5 mmol) of zinc stearate and 15 mL of 1-octadecene were added into another flask, the mixture was heated and stirred under a reduced pressure at 100° C. for degassing for 1 hour while dissolving the raw material to prepare a zinc stearate solution in octadecene at 0.3 M. Into the reaction solution after the core synthesis, 3.0 mL (0.9 mmol) of this solution was added, and the mixture was cooled to 200° C.

Subsequently, 0.474 g (6 mmol) of selenium and 4 mL of trioctylphosphine were added into another flask, and the mixture was heated at 150° C. for dissolving the raw material to prepare a selenium-trioctylphosphine solution at 1.5 M. The selenium-trioctylphosphine solution was added at each 0.1 mL, 0.6 mL (0.9 mmol) in total, while raising the temperature of the reaction solution after the core synthesis step, which was cooled to 200° C., to 320° C. over 30 minutes, the temperature was held at 320° C. for 10 minutes, and then the mixture was cooled to room temperature. Into the mixture, 0.44 g (2.2 mmol) of zinc acetate was added, and the mixture was heated and stirred under a reduced pressure at 100° C. to dissolve zinc acetate.

The flask was purged with nitrogen again, the temperature was raised to 230° C., 0.98 mL (4 mmol) of 1-dodecanethiol was added, and the mixture was retained for 1 hour. The obtained solution was cooled to room temperature to produce a core-shell quantum dot-containing solution.

### (Surface Treatment Step)

As a ligand having a substituent capable of forming a siloxane bond and having a substituent coordinatable on the quantum dot surface, (3-mercaptopropyl)triethoxysilane (Tokyo Chemical Industry Co., Ltd.) was used. Into 2.4 mL of trioctylphosphine, 0.45 g (2 mmol) of zinc bromide was dissolved to produce a zinc precursor solution.

Subsequently, 0.064 g (2 mmol) of sulfur was dissolved into a mixed solution of 1.1 mL of 1-dodecanethiol and 1.1 mL of (3-mercaptopropyl)triethoxysilane to produce a sulfur precursor solution. The core-shell quantum dot-containing solution obtained in the quantum dot shell-layer synthesizing step was heated to 210° C., and 1.25 mL of the aforementioned zinc precursor solution and 1.3 mL of the aforementioned sulfur precursor solution were added.

After the reaction was finished, ethanol was added to precipitate the reaction product, and centrifugal separation was performed to remove the supernatant. The similar purification was performed again, and the product was dispersed in toluene to produce a solution of the dispersed quantum dot on which the ligand having the substituent capable of forming a siloxane bond was coordinated.

### (Surface-Coating Layer Formation Step)

Into a flask purged with nitrogen, triethoxyvinylsilane (4.0 mmol), diphenylsilanediol (6 mmol), barium hydroxide monohydrate (0.15 mmol), and the toluene solution of the dispersed quantum dot after the surface treatment step were added, and the mixture was heated and stirred at 65° C. for 24 hours. After the reaction was finished, the mixture was cooled to room temperature, ethanol was added to precipitate the reaction product, centrifugal separation was performed to remove the supernatant, and the product was dispersed in toluene.

### (Fourier Transform Infrared Spectrometry)

FT-IR measurement was performed by directly dropping the dispersion containing the semiconductor nanoparticles (the quantum dot) onto a detector using a diamond attenuated total reflection (ATR), drying the dispersion sufficiently, and then performing measurement within a measurement range of 400 to 4000 cm⁻¹ with a scanning time of 20. As shown in FIG. 1, it was confirmed that an intensity of a peak A present between 1000 to 1200 cm⁻¹ derived from a Si—O bond was larger than an intensity of a peak B present between 2800 to 3000 cm⁻¹ derived from a C—H bond.

### (Quantum Dot-Containing Composition Mixing Step)

The solution dispersed in toluene after the surface-coating layer formation step and a methacryl-modified silicone oil X-32-3817-3 (Shin-Etsu Chemical Co., Ltd.) were weighed and mixed so that the quantum dot was contained at 20 wt % of a nonvolatile component ratio. After the mixing, the solvent was removed with an evaporator to obtain a quantum dot-containing composition.

### (Step of Manufacturing Wavelength Conversion Member)

The obtained quantum dot-containing composition was used to produce a wavelength conversion member. The quantum dot-containing composition was defoamed with a stirring defoamer, and poured onto a PET film to form a thin film with a bar coater. Then, the formed thin film was irradiated under a nitrogen atmosphere with a UV-LED irradiation apparatus with light at a wavelength of 365 nm and a power of 4000 mW/cm² for 20 seconds for photo-curing the quantum dot-containing resin layer to produce a wavelength conversion member having a thickness of 50 μm.

### (Measurement of Emission Wavelength, Emission Half-Value Width, and Emission Efficiency)

In Examples and Comparative Examples, a quantum efficiency measurement system (QE-2100), manufactured by Otsuka Electronics Co., Ltd., was used for evaluating the fluorescence property of the quantum dot to measure an emission wavelength, a fluorescence half-value width, and fluorescence efficiency (internal quantum efficiency) of the quantum dot at an excitation wavelength of 450 nm.

### (Reliability Test)

The obtained wavelength conversion member was treated under a condition at 85° C. and 85% RH (relative humidity) for 250 hours, and fluorescence efficiency of the wavelength conversion member after the treatment was measured to evaluate its reliability.

### Comparative Example 1

A solution in which a quantum dot was dispersed was obtained in the same manner as in Example 1 until the quantum dot shell-layer synthesizing step.

### (Surface Treatment Step)

As a ligand having a substituent capable of forming a siloxane bond and having a substituent coordinatable on the quantum dot surface, (3-mercaptopropyl)triethoxysilane (Tokyo Chemical Industry Co., Ltd.) (3.0 mmol) was added into the solution in which the quantum dot was dispersed, and the mixture was stirred for 24 hours. After the reaction was finished, the purifying step of adding ethanol to precipitate the quantum dot was performed in the same manner as in Example 1, and the product was dispersed in toluene.

That is, differing from Example 1, the additional ZnS was not formed in the surface treatment step.

### (Surface-Coating Layer Formation Step)

Into a flask purged with nitrogen, triethoxyvinylsilane (4.0 mmol), diphenylsilanediol (6 mmol), barium hydroxide monohydrate (0.15 mmol), and the toluene solution of the dispersed quantum dot after the surface treatment step were added, and the mixture was heated and stirred at 65° C. for 24 hours. After the reaction was finished, the mixture was cooled to room temperature, ethanol was added to precipitate the reaction product, centrifugal separation was performed to remove the supernatant, and the product was dispersed in toluene.

### (Fourier Transform Infrared Spectrometry)

FT-IR measurement was performed by directly dropping the dispersion containing the semiconductor nanoparticles (the quantum dot) onto a detector using a diamond attenuated total reflection (ATR), drying the dispersion sufficiently, and then performing measurement within a measurement range of 400 to 4000 cm⁻¹ with a scanning time of 20. As shown in FIG. 2, an intensity of a peak A present between 1000 to 1200 cm⁻¹ derived from a Si—O bond was smaller than an intensity of a peak B present between 2800 to 3000 cm⁻¹ derived from a C—H bond.

### (Quantum Dot-Containing Composition Mixing Step)

The solution dispersed in toluene after the surface-coating layer formation step and a methacryl-modified silicone oil X-32-3817-3 (Shin-Etsu Chemical Co., Ltd.) were weighed and mixed so that the quantum dot was contained at 20 wt % of a nonvolatile component ratio. After the mixing, the solvent was removed with an evaporator to obtain a quantum dot-containing composition.

### (Step of Manufacturing Wavelength Conversion Member)

The obtained quantum dot-containing composition was used to produce a wavelength conversion member. The quantum dot-containing composition was defoamed with a stirring defoamer, and poured onto a PET film to form a thin film with a bar coater. Then, the formed thin film was irradiated under a nitrogen atmosphere with a UV-LED irradiation apparatus with light at a wavelength of 365 nm and a power of 4000 mW/cm² for 20 seconds for photo-curing the quantum dot-containing resin layer to produce a wavelength conversion member having a thickness of 50 μm. Aggregates were found compared with Example 1, and the quantum yield was decreased compared with Example 1.

### Example 2

A toluene solution in which a quantum dot was dispersed was produced in the same manner as in Example 1 until the surface treatment step.

### (Surface-Coating Layer Formation Step)

Into a flask purged with nitrogen, [(3-triethoxysilyl)propyl]succinic anhydride (Tokyo Chemical Industry Co., Ltd.) (4.0 mmol), diphenylsilanediol (6 mmol), barium hydroxide monohydrate (0.15 mmol), and the toluene solution of the dispersed quantum dot after the surface treatment step were added, and the mixture was heated and stirred at 65° C. for 24 hours. After the reaction was finished, the mixture was cooled to room temperature, ethanol was added to precipitate the reaction product, centrifugal separation was performed to remove the supernatant, and the product was dispersed in toluene.

### (Quantum Dot-Containing Composition Mixing Step)

The solution dispersed in toluene after the surface-coating layer formation step and an acryl resin RA-4101 (Negami Industry) were weighed so that the quantum dot was contained at 20 wt % of a nonvolatile component ratio, and a photo-radical generator Irgacure 1173 was added and mixed at 5 parts by mass based on 100 parts by mass of the acryl resin nonvolatile component. After the mixing, the toluene solvent was removed by distillation under a reduced pressure to obtain a quantum dot-containing composition.

### (Method for Producing Wavelength Conversion Member)

The obtained quantum dot-containing composition was used to produce a wavelength conversion member. The quantum dot-containing composition was degassed in vacuo, the quantum dot-containing composition at a solid-content concentration of 20% was poured into a PTFE-coated mold with 20 cm×10 cm in square and 500 μm in thickness, and the mold was heated on a hotplate at 120° C. for 1 hour to produce a quantum dot-containing resin layer while evaporating the solvent. A part thereof was cut and developed with a PGMEA solution to confirm the absence of a residual film.

Thereafter, the remained quantum dot-containing resin layer was photo-cured by irradiation under a nitrogen atmosphere with a UV-LED irradiation apparatus with light at a wavelength of 365 nm and a power of 4000 mW/cm² for 20 seconds to produce a wavelength conversion member having a thickness of 100 μm.

### Comparative Example 2

A toluene solution in which a quantum dot was dispersed was produced in the same manner as in Comparative Example 1 until the surface treatment step, and a wavelength conversion member was produced in the same manner as in Example 2 except for the above.

### Example 3~

A toluene solution in which a quantum dot was dispersed was produced in the same manner as in Examples 1 and 2 until the surface treatment step.

### (Surface-Coating Layer Formation Step)

Into a flask purged with nitrogen, tris[3-(trimethoxysilyl)propyl]isocyanurate (1.0 mmol), diphenylsilanediol (6 mmol), barium hydroxide monohydrate (0.15 mmol), and the toluene solution of the dispersed quantum dot after the surface treatment step were added, and the mixture was heated and stirred at 65° C. for 24 hours. After the reaction was finished, the mixture was cooled to room temperature, ethanol was added to precipitate the reaction product, centrifugal separation was performed to remove the supernatant, and the product was dispersed in toluene.

### (Quantum Dot-Containing Composition Mixing Step)

An epoxy-containing silicone resin (manufactured by Shin-Etsu Chemical Co., Ltd., CAS No. 2253674-54-1) and the solution dispersed in toluene after the surface-coating layer formation step were weighed and mixed so that the quantum dot was contained at 20 wt % of a nonvolatile component ratio. Based on 100 parts by mass of the silicone resin nonvolatile component, 2 parts by mass of a photo-acid generator CPI-310FG (manufactured by San-Apro Ltd.) and 20 parts by mass of a crosslinker THI-DE were weighed and mixed. After the mixing, the toluene solvent was removed by distillation under a reduced pressure to obtain a quantum dot-containing composition.

### (Method for Producing Wavelength Conversion Member)

The obtained quantum dot-containing composition was used to produce a wavelength conversion member. The quantum dot-containing composition was degassed in vacuo, the quantum dot-containing composition at a solid-content concentration of 20% was poured into a PTFE-coated mold with 20 cm×10 cm in square and 500 μm in thickness, and the mold was heated on a hotplate at 120° C. for 1 hour to produce a quantum dot-containing resin layer while evaporating the solvent. A part thereof was cut and developed with a PGMEA solution to confirm the absence of a residual film.

Thereafter, the remained quantum dot-containing resin layer was photo-cured by irradiation under a nitrogen atmosphere with a UV-LED irradiation apparatus with light at a wavelength of 365 nm and a power of 4000 mW/cm² for 20 seconds to produce a wavelength conversion member having a thickness of 100 μm.

### Comparative Example 3

A toluene solution in which a quantum dot was dispersed was produced in the same manner as in Comparative Example 1 until the surface treatment step, and a wavelength conversion member was produced in the same manner as in Example 3 except for the above.

### Example 4

A toluene solution in which a quantum dot was dispersed was produced in the same manner as in Examples 1, 2, and 3 until the surface treatment step.

### (Surface-Coating Layer Formation Step)

Into a flask purged with nitrogen, triethoxysilylpropyl methacrylate (4.0 mmol), diphenylsilanediol (6 mmol), barium hydroxide monohydrate (0.15 mmol), and the toluene solution of the dispersed quantum dot after the surface treatment step were added, and the mixture was heated and stirred at 65° C. for 24 hours. After the reaction was finished, the mixture was cooled to room temperature, ethanol was added to precipitate the reaction product, centrifugal separation was performed to remove the supernatant, and the product was dispersed in toluene.

### (Quantum Dot-Containing Composition Mixing Step)

A phenol-crosslinkable silicone resin (manufactured by Shin-Etsu Chemical Co., Ltd., CAS No. 916059-41-1) and the solution dispersed in toluene after the surface-coating layer formation step were weighed and mixed so that the quantum dot was contained at 20 wt % of a nonvolatile component ratio. Based on 100 parts by mass of the silicone resin nonvolatile component, 2 parts by mass of a photo-acid generator CPI-310FG (manufactured by San-Apro Ltd.) and 20 parts by mass of a crosslinker THI-DE were weighed and mixed. After the mixing, the toluene solvent was removed by distillation under a reduced pressure to obtain a quantum dot-containing composition.

### (Method for Producing Wavelength Conversion Member)

The obtained quantum dot-containing composition was used to produce a wavelength conversion member. The quantum dot-containing composition was degassed in vacuo, the quantum dot-containing composition at a solid-content concentration of 20% was poured into a PTFE-coated mold with 20 cm×10 cm in square and 500 μm in thickness, and the mold was heated on a hotplate at 120° C. for 1 hour to produce a quantum dot-containing resin layer while evaporating the solvent. A part thereof was cut and developed with a PGMEA solution to confirm the absence of a residual film.

Thereafter, the remained quantum dot-containing resin layer was photo-cured by irradiation under a nitrogen atmosphere with a UV-LED irradiation apparatus with light at a wavelength of 365 nm and a power of 4000 mW/cm² for 20 seconds to produce a wavelength conversion member having a thickness of 100 μm.

### Comparative Example 4

A toluene solution in which a quantum dot was dispersed was produced in the same manner as in Comparative Example 1 until the surface treatment step, and a wavelength conversion member was produced in the same manner as in Example 4 except for the above.

Table 1 shows the comparison results between Examples 1 to 4 and Comparative Examples 1 to 4.

TABLE 1

| | | Exam- | Exam- | Exam- | Exam- | Comparative | Comparative | Comparative | Comparative |
|---|---|---|---|---|---|---|---|---|---|
| | | ple 1 | ple 2 | ple 3 | ple 4 | Example 1 | Example 2 | Example 3 | Example 4 |
| After | Wavelength (nm) | 536 | ← | ← | ← | ← | ← | ← | ← |
| synthesizing | Half-value width (nm) | 41 | ← | ← | ← | ← | ← | ← | ← |
| quantum dot | Internal quantum | 68 | ← | ← | ← | ← | ← | ← | ← |
| | efficiency (%) | | | | | | | | |
| After surface | Wavelength (nm) | 536 | ← | ← | ← | 536 | ← | ← | ← |
| treatment | Half-value width (nm) | 41 | ← | ← | ← | 41 | ← | ← | ← |
| step | Internal quantum | 78 | ← | ← | ← | 64 | ← | ← | ← |
| | efficiency (%) | | | | | | | | |
| After forming | Wavelength (nm) | 536 | ← | 536 | 536 | 536 | 536 | 536 | 536 |
| surface- | Half-value width (nm) | 41 | ← | 42 | 41 | 41 | 41 | 41 | 41 |
| coating layer | Internal quantum | 75 | ← | 74 | 76 | 68 | 64 | 66 | 67 |
| FTIR result | efficiency (%) | | | | | | | | |
| | Size of peaks A and B | A > B | ← | ← | ← | A < B | ← | ← | ← |
| Quantum dot- | Wavelength (nm) | 536 | 537 | 539 | 534 | 539 | 540 | 539 | 540 |
| containing | Half-value width (nm) | 41 | 42 | 41 | 42 | 46 | 48 | 46 | 48 |
| composition | Internal quantum | 70 | 68 | 68 | 72 | 66 | 61 | 63 | 55 |
| | efficiency (%) | | | | | | | | |
| Wavelength | Wavelength (nm) | 536 | 538 | 539 | 534 | 536 | 544 | 542 | 544 |
| conversion | Half-value width (nm) | 41 | 42 | 42 | 42 | 48 | 49 | 52 | 51 |
| member | Internal quantum | 62 | 59 | 58 | 64 | 39 | 38 | 39 | 33 |
| | efficiency (%) | | | | | | | | |
| Change in internal | Decreasing rate (%) | 3 | 5 | 10 | 8 | 4 | 10 | 15 | 12 |
| quantum efficiency | | | | | | | | | |
| through reliability | | | | | | | | | |
| test | | | | | | | | | |

| | | | | | | | | |
|---|---|---|---|---|---|---|---|---|
| Presence/absence of aggregate in | Absence | Absence | Absence | Absence | Presence | Presence | Presence | Presence |
| wavelength conversion member | | | | | | | | |

Tables 1 shows: the emission wavelength, the fluorescence half-value width, and the internal quantum efficiency after synthesizing the quantum dot, after the surface treatment step, after forming the surface-coating layer, after the mixing step (the quantum dot-containing composition), and after curing the quantum dot-containing composition (the wavelength conversion member); the decreasing rate of the internal quantum efficiency through the reliability test; and presence/absence of aggregate in the wavelength conversion member. Table 1 also shows the result of FT-IR after forming the surface-coating layer.

From the results in Table 1, all Examples exhibited the peak A in FT-IR larger than the peak B after forming the surface-coating layer. In contrast, Comparative Examples exhibited the peak B larger than the peak A, and poor internal quantum efficiency after the surface treatment step, after forming the surface-coating layer, and after producing the quantum dot-containing composition.

Further, it was found that Comparative Examples exhibited decreased internal quantum efficiency after producing the wavelength conversion member and larger shift of the emission wavelength to a longer wavelength compared with Examples. It was considered that Comparative Examples caused insufficient dispersing stability to produce the aggregate.

In addition, comparing the results of the reliability test (the treatment at 85° C. and 85% RH for 250 hours) of Examples and Comparative Examples, the stability were equivalent due to formation of the surface-coating layer, but deterioration in Comparative Examples was large compared with Examples.

As above, it has been found that the decreasing rate of the internal quantum efficiency through the 250-hour treatment (the decreasing rate of the internal quantum efficiency after the treatment) can be suppressed within 10% in Examples without a barrier film in the reliability test at 85° C. and 85% RH to enable stabilization.

As above, it has been confirmed that the quantum dot-containing composition in the present invention exhibits high internal quantum efficiency and stability, has good film quality after curing, and can be applied for a quantum dot-containing resist and a quantum dot-containing ink for inkjet.

Note that the present invention is not limited to the above-described embodiments. The embodiments are examples, and any examples that substantially have the same feature and demonstrate the same functions and effects as those in the technical concept described in claims of the present invention are included in the technical scope of the present invention.

1-5. (canceled)

6. A quantum dot-containing composition, comprising a quantum dot that emits fluorescence by excitation light, wherein
the quantum dot-containing composition is a mixture of the quantum dot and a polymerizable polymer composition, the quantum dot has a core-shell structure, an outermost shell is of ZnS, and a surface of the quantum dot contains a surface-coating layer having a siloxane bond, and
the quantum dot has a peak intensity present between 1000 to 1200 cm⁻¹ that is larger than a peak intensity present between 2800 to 3000 cm⁻¹, measured by Fourier transform infrared spectrometry.

7. The quantum dot-containing composition according to claim 6, wherein the surface-coating layer has any one or more reactive substituents of a vinyl group, an acryl group, a methacryl group, a hydroxy group, a phenolic hydroxy group, and an epoxy group.

8. The quantum dot-containing composition according to claim 7, wherein a polymer contained in the polymerizable polymer composition has any one or more of a vinyl group, an acryl group, a methacryl group, a hydroxy group, a phenolic hydroxy group, and an epoxy group as a substituent polymerizable with the reactive substituent.

9. A wavelength conversion member, being a cured product of the quantum dot-containing composition according to claim 6.

10. A wavelength conversion member, being a cured product of the quantum dot-containing composition according to claim 7.

11. A wavelength conversion member, being a cured product of the quantum dot-containing composition according to claim 8.

12. A method for manufacturing a quantum dot-containing composition comprising a quantum dot that emits fluorescence by excitation light, the method comprising:
a surface treatment step of heating and mixing a solution containing a dispersed quantum dot in which ZnS is formed in an outermost shell, a ligand having a substituent capable of forming a siloxane bond and having a thiol group, and a solution containing a zinc precursor and a sulfur precursor, to coordinate the ligand while forming an additional ZnS on an outermost surface of the quantum dot;
a surface-coating layer formation step of performing a reaction between the substituent capable of forming a siloxane bond and a compound capable of forming a siloxane bond and having a reactive substituent, to form a surface-coating layer having a siloxane bond, after the surface treatment step; and
a mixing step of adding and mixing a polymerizable polymer composition containing a substituent polymerizable with the reactive substituent, after the surface-coating layer formation step.
